(19) United States
(12) Patent Application Publication
(10) Pub. No.: US 2008/0303869 A1
(43) Pub. Date: Dec. 11, 2008

(54) INK JET PRINT HEAD AND MANUFACTURING METHOD THEREOF

(75) Inventors: Sung Joon PARK, Suwon-si (KR); Byung Ha PARK, Suwon-si (KR); Dong Sik SHIM, Suwon-si (KR); Kyong Il KIM, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/054,585

(22) Filed: Mar. 25, 2008

(30) Foreign Application Priority Data
Jun. 7, 2007 (KR) 2007-55700

(51) Int. Cl. G03F 7/26; B41J 2/04

(52) U.S. Cl. 347/54; 430/320

(57) ABSTRACT

An ink jet print head and a manufacturing method thereof that is improved so as to simplify a glue layer forming process including a glue layer of the ink jet print head is made of a silicone modified resin having a photosensitive property, such as a silicone modified polyimide resin. The glue layer can be formed by coating a silicone modified polyimide resin solution on a substrate, forming a silicone modified polyimide resin layer by vaporizing a solvent from the coated silicone modified polyimide resin solution, and patterning the silicone modified polyimide resin layer.

### CROSS-REFERENCE TO RELATED APPLICATIONS

This application claims priority under 35 U.S.C. §119(a) from Korean Patent Application No. 2007-0055700, filed on Jun. 7, 2007 in the Korean Intellectual Property Office, the disclosure of which is incorporated herein in its entirety by reference.

### BACKGROUND OF THE INVENTION

1. Field of the Invention

The present general inventive concept relates to an ink jet print head and a manufacturing method thereof, and more particularly to an ink jet print head and a manufacturing method thereof which has a glue layer provided between a substrate and a flow channel layer disposed on the substrate.

2. Description of the Related Art

An ink jet print head is a device which forms an image by ejecting ink droplets onto a desired position on recording paper. An ink jet print head generally includes a substrate which is provided with an ejection pressure generating element for ink ejection on a surface thereof, and a flow channel layer which is disposed on the substrate and forms ink passages. A passivation layer may be provided on the substrate to protect the ejection pressure generating element. This protective layer is typically made of an inorganic substance containing silicone.

Contact surfaces between the flow channel layer and the substrate (or the passivation layer) are boundary surfaces in which substances having different properties meet. The contact surfaces have weak durability. Therefore, a glue layer is provided between the substrate and the flow channel layer to increase a bonding force, an example provided in Japanese Patent Laid-Open Publication No. 11-348290.

The ink jet print head identified above relates to a liquid passage-forming member bonded to a substrate with a glue layer made of a polyether amide resin therebetween. The glue layer made of a polyether amide resin is formed by the following processes. A polyether amide resin is coated on the substrate by a spin coating method, and a photoresist pattern used as an etching mask is formed on the polyether amide layer. Next, the glue layer is formed by patterning the polyether amide layer through O2 plasma ashing, and the photoresist pattern used as the mask is removed.

However, the above conventional ink jet print head has a problem of low productivity due to such complicated manufacturing processes including the photolithography process for forming the glue layer by patterning the polyether amide layer, the etching process and the photoresist removing process. Further, because a large amount of equipment is required to perform such processes, investment and maintenance costs are increased and result in a large economic burden.

### SUMMARY OF THE INVENTION

The general inventive concept provides an ink jet print head and a manufacturing method thereof that is improved so as to simplify a glue layer forming process.

Additional aspects and/or utilities of the present general inventive concept will be set forth in part in the description which follows and, in part, will be obvious from the description, or may be learned by practice of the general inventive concept.

The foregoing and/or other aspects and utilities of the general inventive concept may be achieved by providing an ink jet print head including a substrate, a flow channel layer disposed on the substrate, and a glue layer provided between the substrate and the flow channel layer, the glue layer being made of a silicone modified resin having a photosensitive property.

The silicone modified resin may include a silicone modified polyimide resin.

The glue layer may be formed through a photolithography process.

The foregoing and/or other aspects and utilities of the general inventive concept may also be achieved by providing a method of manufacturing an ink jet print head, the method including preparing a substrate provided with an ejection pressure generating element to eject ink, forming a glue layer made of a silicone modified polyimide resin on the substrate and forming a flow channel layer to define ink passages on the glue layer.

The forming of the glue layer may include coating a silicone modified polyimide resin solution on the substrate, forming a silicone modified polyimide resin layer by vaporizing a solvent from the coated silicone modified polyimide resin solution, and patterning the silicone modified polyimide resin layer.

The patterning of the silicone modified polyimide resin layer may be performed through a photolithography process.

The foregoing and/or other aspects and utilities of the general inventive concept may also be achieved by providing a method of manufacturing an ink jet print head, the method comprising preparing a substrate provided with a heat generating layer to heat ink, forming a glue layer on the substrate through a photolithography process using a silicone modified resin having a photosensitive property and forming a flow channel layer to define ink passages on the glue layer through a photolithography process.

The silicone modified resin may include a silicone modified polyimide resin.

The foregoing and/or other aspects and utilities of the general inventive concept may also be achieved by providing an ink jet print head including a passivation layer, a flow channel layer, and a glue layer disposed between and in contact with the passivation layer and the flow channel layer, the glue layer being made of a silicone modified polyimide resin.

The foregoing and/or other aspects and utilities of the general inventive concept may also be achieved by providing a method of manufacturing an ink jet print head, the method including forming a passivation layer and a flow channel layer, and forming a silicone modified resin layer disposed between and in contact with the passivation layer and the flow channel layer.

The forming of the silicone modified resin layer may include coating a silicone modified polyimide resin solution on at least the passivation layer, forming a silicone modified polyimide resin layer by vaporizing a solvent from the coated silicone modified polyimide resin solution and patterning the silicone modified polyimide resin layer.

### BRIEF DESCRIPTION OF THE DRAWINGS

These and/or other aspects and utilities of the exemplary embodiments of the present general inventive concept will become apparent and more readily appreciated from the following description of the embodiments, taken in conjunction with the accompanying drawings, of which:

FIG. 1 is a sectional view illustrating an ink jet print head in accordance with an embodiment of the present general inventive concept;

FIGS. 2 to 11 are views illustrating a method of manufacturing the ink jet print head in accordance with embodiments of the present general inventive concept; and

FIG. 12 is a flowchart illustrating a method of manufacturing an ink jet print head according to an embodiment of the present general inventive concept.

### DETAILED DESCRIPTION OF THE PREFERRED EMBODIMENTS

Reference will now be made in detail to exemplary embodiments of the present general inventive concept, examples of which are illustrated in the accompanying drawings, wherein like reference numerals refer to like elements throughout. The embodiments are described below in order to explain the present general inventive concept by referring to the figures.

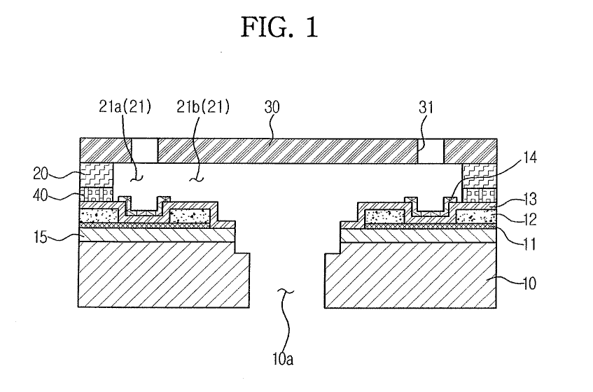

FIG. 1 is a sectional view illustrating an ink jet print head in accordance with an embodiment of the present general inventive concept.

Referring to FIG. 1, in an embodiment, an ink jet print head ca be an electro-thermal type ink jet print head to generate bubbles in ink using a heat source and to eject ink droplets by an expansive power of the bubbles. As illustrated in FIG. 1, the ink jet print head of this embodiment includes a substrate 10, on which a heat generating layer 11 is provided as an ejection pressure generating element for ink ejection. Electrodes 12, a passivation layer 13 and anti-cavitation layers 14 are provided on the heat generating layer 11. Also, a flow channel layer 20 defining ink passages 21 is disposed on the substrate 10, and a nozzle layer 30 forming nozzles 31 for ink ejection is disposed on the flow channel layer 20. A glue layer 40 is provided between the flow channel layer 20 and the substrate 10. The glue layer 40 functions to stably bond the flow channel layer 20 onto the substrate 10.

The substrate 10 is configured as a silicon wafer, and is formed with an ink supply hole 10a through which the ink is supplied from an ink storage unit (not illustrated). The heat generating layer 11 provided on the substrate 10 is a typical thin film heater, to heat the ink by converting an electric signal transmitted from the electrodes 12 into a thermal energy. The heat generating layer 11 may be made of a metal material, such as tantalum nitride (TaN) or tantalum-aluminum (Ta—Al). The electrodes 12 are disposed on the heat generating layer 11, and receive an electric signal from a typical CMOS logic and a power transistor and transmit the electric signal to the heat generating layer 11. A heat storage layer 15 may be provided between the heat generating layer 11 and the substrate 10, as an insulation layer configured as a silicon oxide film. The heat storage layer 15 functions to prevent the heat generated from the heat generating layer 11 from escaping to the substrate 10.

The passivation layer 13 is provided on and in contact with the heat generating layer 11 and the electrodes 12 to protect the heat generating layer 11 and the electrodes 12. The passivation layer 13 may be configured as a silicon nitride (SiN) film which has a good insulation property and heat transfer efficiency. The anti-cavitation layers 14 may be provided on the passivation layer 13, at positions corresponding to the nozzles 31. The anti-cavitation layers 14 prevent the heat generating layer 11 from being broken due to cavitation force which is generated when the ink bubbles formed by the thermal energy contract.

The flow channel layer 20 defines the ink passages 21 which connect the ink supply hole 10a and the nozzles 31. Each ink passage 21 has an ink chamber 21a in which the ink is filled, and a restrictor 21b to connect the ink supply hole 10a and the ink chamber 21a.

The glue layer 40 can be made of a silicone modified resin which has a photosensitive property, such as a silicone modified polyimide resin.

The silicone modified resin is a resin formed by copolymerizing silicone with organic reactive monomer (oligomer), e.g., an acrylic resin, a urethane resin, a polyester resin, a polycarbonate resin, and a polyimide resin, which are copolymerized with silicone. The silicone modified polyimide resin is a material which has a heat resistance property of polyimide and flexibility and adhesiveness of silicone. The silicone modified polyimide resin is not easily deformed and is in contact with the ink of a high temperature, and can effectively prevent the flow channel layer 20 from being exfoliated from the substrate 10 (or the passivation layer 13) due to a difference of thermal expansion coefficients. Also, in the present embodiment, since the glue layer 40 can be patterned only by a photolithography process using a photosensitive resin, the process to pattern the glue layer 40 can be simplified.

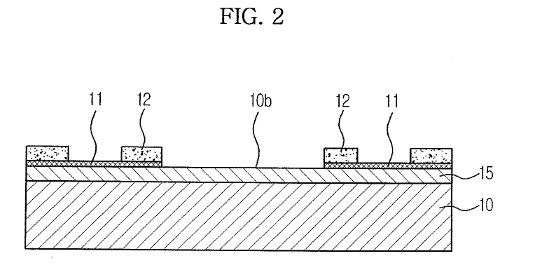

Hereinafter, a method of manufacturing the ink jet print head according to embodiments of the present general inventive concept will be described with reference to FIGS. 2 to 11.

As illustrated in FIG. 2, the substrate 10, which is provided with the heat generating layer 11 and the electrodes 12 on a front surface 10b thereof, is prepared. The heat generating layer 11 may be formed by depositing a heat resistant material, such as tantalum nitride or a tantalum-aluminum alloy, on the substrate 10 by sputtering or chemical vapor deposition, and patterning the same. The electrodes 12 may be formed by depositing a metal material having a sufficient conductivity, such as aluminum, by sputtering, and patterning the same. The heat storage layer 15 may be provided between the heat generating layer 11 and the substrate 10. The heat storage layer 15 may be formed by heating a surface of the substrate 10, for example a silicon substrate, at a high temperature.

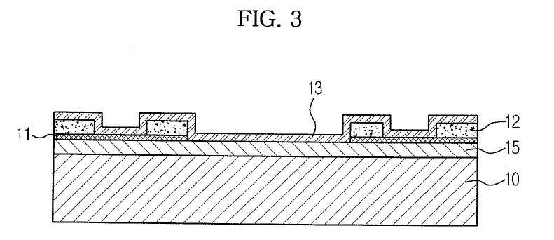

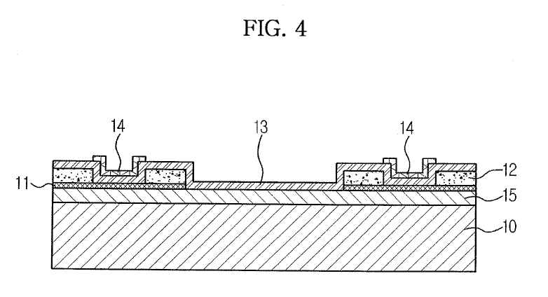

As illustrated in FIG. 3, the passivation layer 13 is formed on the substrate 10 on which the heat generating layer 11 and the electrodes 12 have been formed. The passivation layer 13 may be formed by depositing SiNx or SiOx, which has good insulation and heat transfer properties, and patterning the same. As illustrated in FIG. 4, the anti-cavitation layer 14 is formed on the passivation layer 13, at positions corresponding to the nozzles 31 (FIG. 1). The anti-cavitation layer 14 may be formed by depositing tantalum (Ta) and patterning the same.

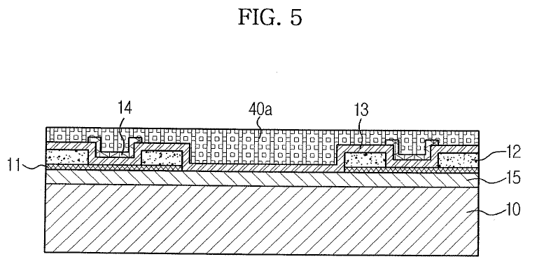

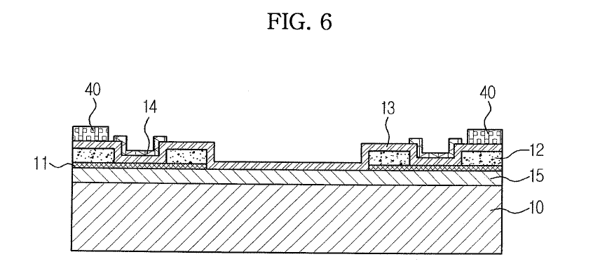

As illustrated in FIGS. 5, and 6, the glue layer 40 is formed on the substrate 10 on which the heat generating layer 11, the electrodes 12, the passivation layer 13 and the anti-cavitation layer 14 have been formed. The glue layer 40 is formed through a photolithography process using silicone modified polyimide having a photosensitive property. The silicone modified polyimide can have a photosensitive property. Thus, a product of model No. SPS-3750 2.0 manufactured by Shin Etsu company (Japan) to be used with material having a photosensitive property can be used. More particularly, the glue layer 40 can be formed through the following processes. As illustrated in FIG. 5, a silicone modified polyimide resin layer 40a is formed by coating a silicone modified polyimide resin solution on the substrate 10 by a spin coating method and vaporizing a solvent. Next, by patterning the silicone modified polyimide resin layer 40a, the glue layer 40 is formed as illustrated in FIG. 6. That is, the glue layer 40 is formed by exposing the silicone modified polyimide resin layer 40a to light and removing a portion which is not exposed to light by using an alkalescent developer (e.g., 300 MIF manufactured by AZ company). At this time, the glue layer 40 is formed to cover a predetermined region on which the flow channel layer 20 is scheduled to be deposited.

As described in the present embodiment, the manufacturing processes of the ink jet print head can be simplified because the glue layer can be formed only through a photolithography process without performing other complicated processes, such as a process of forming an additional photoresist pattern to pattern the glue layer, an etching process, a process of removing the photoresist pattern after the patterning, and the like.

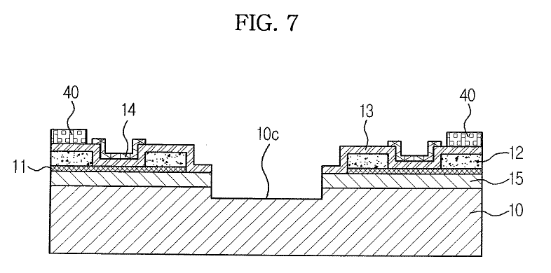

As illustrated in FIG. 7, a trench 10c is formed on the front surface of the substrate 10. The trench 10c has a function of guiding the ink supply hole 10a to be formed regularly near the front surface of the substrate 10. The trench 10c may be formed by dry etching, e.g., reactive ion etching (RIE) using plasma, or sand blasting.

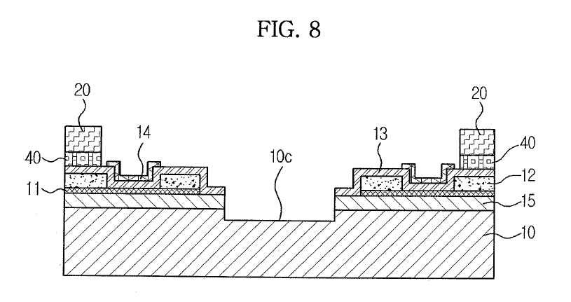

As illustrated in FIG. 8, the flow channel layer 20 is formed on the glue layer 40 by a photolithography process. Although not illustrated in the drawing, this process includes operations of coating a negative photoresist on the substrate 10 by a spin coating method, exposing the photoresist layer to light by using a photomask having an ink chamber pattern and a restrictor pattern, and developing the photoresist layer to selectively remove the photoresist which is not exposed to light. Thus, forming the flow channel layer 20 defining the ink passages 21 (FIG. 1) as illustrated in FIG. 8. The flow channel layer 20 may be formed using an epoxy resin or a polyimide resin.

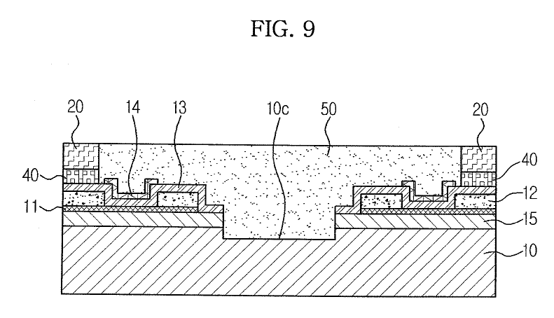

As illustrated in FIG. 9, a sacrificial layer 50 is formed to cover the front surface of the substrate 10 and the flow channel layer 20. The upper surfaces of the sacrificial layer 50 and the flow channel layer 20 are flattened through a chemical mechanical polish (CMP) process so that the flow channel layer 20 and the sacrificial layer 50 have a same height. By this, since the nozzle layer 30 formed on the flow channel layer 20 can closely contact the flow channel layer 20, the durability of the print head is increased, and a shape and a dimension of the ink passage 21 are controlled accurately, thereby improving ink ejection performance of the print head. The sacrificial layer 50 may be formed by coating a positive photoresist by a spin coating method. Because the sacrificial layer 50 is exposed to an etching solution when etching the substrate to form the ink supply hole, the sacrificial layer 50 can be made of a material having a strong resistance to the etching solution.

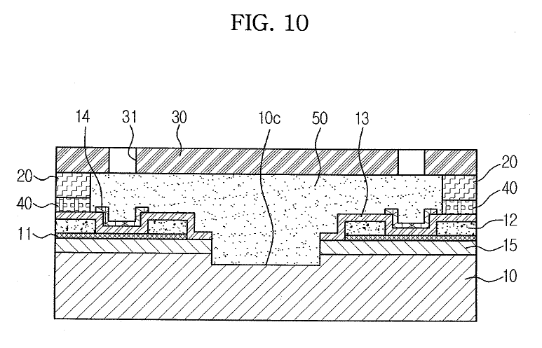

As illustrated in FIG. 10, the nozzle layer 30 is formed on the flattened sacrificial layer 50 and flow channel layer 20. The nozzle layer 30 is formed by a photolithography process, similarly to the flow channel layer 20. That is, after a photoresist is coated on the flow channel layer 20, the photoresist is exposed to light through a photomask having a nozzle pattern, and is developed to selectively remove a portion which is not exposed to light, thereby forming the nozzle layer 30 having the nozzles 31 as illustrated in FIG. 10.

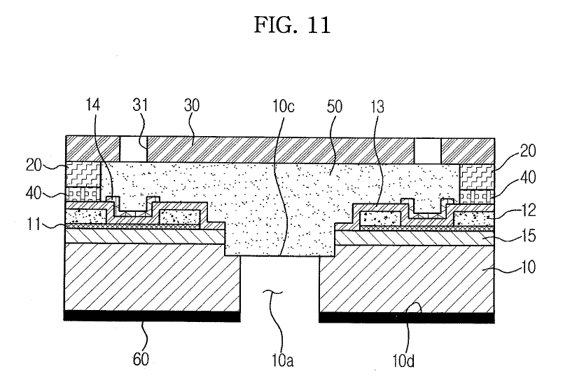

As illustrated in FIG. 11, an etching mask 60 is formed on a rear surface 10d of the substrate 10 to form the ink supply hole. After forming the etching mask 60, the substrate 10 is etched from an area of the rear surface 10d exposed by the etching mask 60 until the trench 10c is exposed, thereby forming the ink supply hole 10a.

The etching mask 60 may be formed by coating a positive or negative photoresist on the rear surface 10d of the substrate 10, and patterning the same. When etching the substrate 10, a wet etching method adequate for mass production can be used. In this case, as the etching solution, potassium hydroxide (KOH), sodium hydroxide (NaOH), or tetramethyl ammonium hydroxide (TMAH) can be used.

Finally, by removing the etching mask 60 and the sacrificial layer 50 from a workpiece illustrated in FIG. 11, a manufacturing of the ink jet print head illustrated in FIG. 1 is completed.

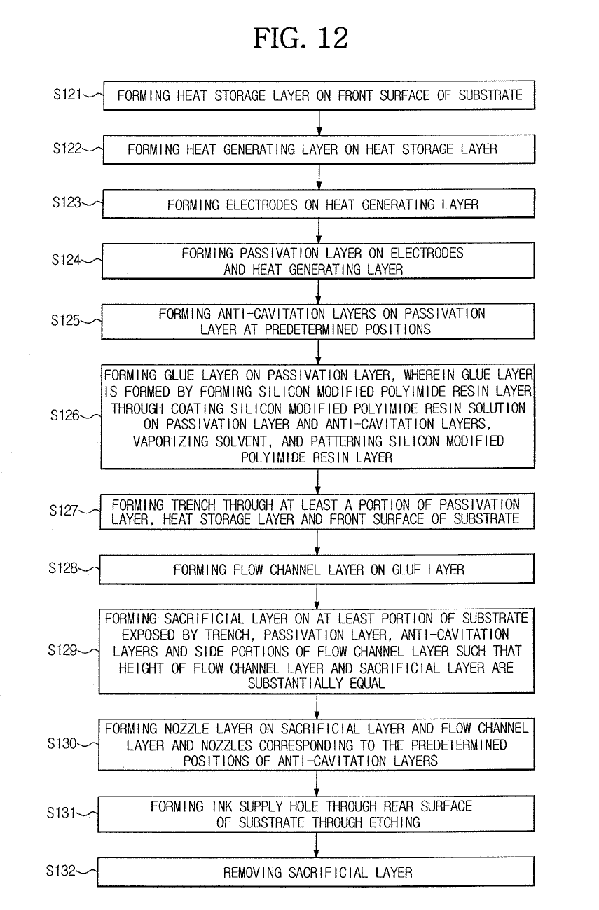

FIG. 12 is a flowchart illustrating a method of manufacturing an ink jet print head according to an embodiment of the present general inventive concept. Referring to FIG. 12, in the present embodiment, in operation S121, a heat storage layer 15 is formed on a front surface of a substrate 10. In operation S122, a heat generating layer 11 is formed on the heat storage layer 15. In operation S123, electrodes 12 are formed on the heat generating layer 11. In operation S124, a passivation layer 13 is formed on the electrodes 12 and the heat generating layer 11. In operation S125, anti-cavitation layers 14 are formed on the passivation layer 13 at predetermined positions. In operation S126, a glue layer 40 is formed on the passivation layer 13, wherein the glue layer 40 is formed, for example, by forming a silicon modified polyimide resin layer through coating a silicon modified polyimide resin solution on the passivation layer 13 and the anti-cavitation layers 14, vaporizing a solvent thereof, and patterning the silicon modified polyimide resin layer. In operation S127, a trench 10c is formed through at least a portion of the passivation layer 13, the heat storage layer 15 and the front surface of the substrate 10. In operation S128, a flow channel layer 20 is formed on the glue layer 40. In operation S129, a sacrificial layer 50 is formed, for example, on at least a portion of the substrate 10 exposed by the trench 10c, the passivation layer 13, the anti-cavitation layers 14 and side portions of the flow channel layer 20 such that a height of the flow channel layer 20 and the sacrificial layer 50 are substantially equal. In operation S130, a nozzle layer 30 is formed on the sacrificial layer 50 and the flow channel layer 20. Nozzles 31, for example, can be formed at the nozzle layer 30 corresponding to the predetermined positions of the anti-cavitation layers 14. In operation S131, an ink supply hole 10a is formed through a rear surface of the substrate 10 through etching. In operation S132, the sacrificial layer 50 is removed.

As apparent from the above description, the ink jet print head according to various embodiments of the present general inventive concept can increase durability by stably bonding a flow channel layer on the substrate by forming a glue layer using a silicone modified resin having good adhesiveness, heat resistance and tolerance to ink. Further, since a process of forming the glue layer is simple, productivity can be increased, and investment and maintenance costs for process equipment can be saved.

Although various embodiments of the present general inventive concept have been illustrated and described, it would be appreciated by those skilled in the art that changes may be made in these embodiments without departing from the principles and spirit of the general inventive concept, the scope of which is defined in the appended claims and their equivalents.

What is claimed is:

1. An ink jet print head, comprising:
a substrate;
a flow channel layer disposed on the substrate; and
a glue layer provided between the substrate and the flow channel layer, the glue layer being made of a silicone modified resin having a photosensitive property.

2. The ink jet print head according to claim 1, wherein the silicone modified resin comprises:
a silicone modified polyimide resin.

3. The ink jet print head according to claim 1, wherein the glue layer is formed through a photolithography process.

4. A method of manufacturing an ink jet print head, the method comprising:
preparing a substrate provided with an ejection pressure generating element to eject ink;
forming a glue layer made of a silicone modified polyimide resin on the substrate; and
forming a flow channel layer to define ink passages on the glue layer.

5. The method according to claim 4, wherein the forming of the glue layer comprises:
coating a silicone modified polyimide resin solution on the substrate;
forming a silicone modified polyimide resin layer by vaporizing a solvent from the coated silicone modified polyimide resin solution; and
patterning the silicone modified polyimide resin layer.

6. The method according to claim 5, wherein the patterning of the silicone modified polyimide resin layer is performed through a photolithography process.

7. A method of manufacturing an ink jet print head, the method comprising:
preparing a substrate provided with a heat generating layer to heat ink;
forming a glue layer on the substrate through a photolithography process using a silicone modified resin having a photosensitive property; and
forming a flow channel layer to define ink passages on the glue layer through a photolithography process.

8. The method according to claim 7, wherein the silicone modified resin comprises:
a silicone modified polyimide resin.

9. An ink jet print head, comprising:
a passivation layer;
a flow channel layer; and
a glue layer disposed between and in contact with the passivation layer and the flow channel layer, the glue layer being made of a silicone modified polyimide resin.

10. A method of manufacturing an ink jet print head, the method comprising:
forming a passivation layer and a flow channel layer; and
forming a silicone modified resin layer disposed between and in contact with the passivation layer and the flow channel layer.

11. The method according to claim 10, wherein the forming of the silicone modified resin layer comprising:
coating a silicone modified polyimide resin solution on at least the passivation layer;
forming a silicone modified polyimide resin layer by vaporizing a solvent from the coated silicone modified polyimide resin solution; and
patterning the silicone modified polyimide resin layer.
